(19) United States
(12) Patent Application Publication
(10) Pub. No.: US 2015/0331015 A1
(43) Pub. Date: Nov. 19, 2015

(54) FLUX-GATE TYPE NON-CONTACT CURRENT MEASURING DEVICE

(71) Applicant: Sangchul LEE, (US)

(72) Inventor: Sang Chul LEE, Yongin-si (KR)

(73) Assignee: HISEN TECH Co., Ltd., Daejeon (KR)

(21) Appl. No.: 14/439,631

(22) PCT Filed: Oct. 25, 2013
(86) PCT No.: PCT/KR2013/009561

§ 371 Date: Apr. 29, 2015

(30) Foreign Application Priority Data
Oct. 31, 2012 (KR) 10-2012-0122450

(51) Int. Cl. G01R 15/20; G01R 19/00

(52) U.S. Cl. CPC G01R 15/20; G01R 19/0092

(57) ABSTRACT

The present invention relates to a flux-gate type non-contact current measuring device for measuring a current to be measured by detecting an electromagnetic field around a conducting wire into which the current to be measured flows, wherein the present invention can detect a direct current component through a change of an oscillating signal by applying the oscillating signal for magnetizing two cores in mutually opposite polarities, wherein: an LC oscillation circuit is formed by using the inductance of a coil wound on one core, and the direct current component is detected by applying an LC-oscillating signal to a coil wound on the other core; an alternating current component is detected by using another core; compensated currents corresponding to the detected direct current and alternating current components are converged under a condition of offsetting a magnetic flux by the current to be measured so that the current to be measured can be measured by measuring the compensated currents in the converged state thereof; and the present invention can normally measure a current by automatically demagnetizing an LC oscillating core even in a circumstance that the LC oscillating core is saturated by the current to be measured.

### TECHNICAL FIELD

The present invention relates to a flux-gate type non-contact current measuring device for measuring a current to be measured by detecting an electromagnetic field around a conducting wire through which the current to be measured flows, wherein the present invention can detect a DC component through a change in an oscillating signal by applying the oscillating signal for magnetizing two cores in opposite polarities, wherein an LC oscillation circuit is formed by using the inductance of a coil wound around one core, and the DC component is detected by applying an LC-oscillating signal to a coil wound around the other core; an AC component is detected by using another core; compensated currents corresponding to the detected direct current and alternating current components are converged under a condition of canceling out a magnetic flux by the current to be measured, so that the current to be measured can be measured by measuring the compensated currents in the converged state thereof; and the present invention can normally measure to current by automatically demagnetizing an LC oscillating core even n a circumstance that the LC oscillating core is saturated by the current to be measured.

### DISCUSSION OF RELATED ART

Methods for measuring current flowing through a conducting wire include direct measuring methods in which a current measuring device is directly connected to the conducting wire to measure the current and indirect measuring methods in which an electromagnetic field generated around the conducting wire by the current is detected by a current measuring device to measure the current flowing through the conducting wire.

The direct measuring methods, requiring a connection with a measuring device, are bothersome and have the limitation that a circuit-wise disconnection is impossible. Accordingly, the indirect measuring methods free of such limitation gain popularity.

A representative indirect measuring method is the flux-gate type current measuring method. According to the flux-gate type current measuring method, an AC current is applied to two cores so that their AC magnetization directions are opposite each other, and variations in the electromotive forces respectively generated from the respective coil windings on the to cores are sensed to detect the DC magnetic flux created by the current flowing through the conducting wire. In a configuration, the AC magnetic flux created by the current flowing through the conducting wire is detected using a separate coil, and the current corresponding to the detected DC magnetic flux and AC magnetic flux is applied to cancel out the electromagnetic fields created by the current flowing through the conducting wire. The current flowing through the conducting wire is measured by detecting the applied current.

There are some conventional techniques star measuring a current in the flux-gate method, which are disclosed in Korean Utility Model Registration No. 20-0283971, Korean Patent Application Publication No. 10-2010-0001504, and Korean Patent Application Publication No. 10-2004-0001535. According to the conventional techniques, a current oscillated in a rectangular wave or sinusoidal wave is applied to two cores to magnetize the cores in opposite directions thereof, and in the state, a distortion caused in the two cores by an influence from an electromagnetic field created by the current under measurement, flowing through the conducting wire, is sensed as a voltage signal, and the DC component of the distortion is detected. The AC component of the distortion is detected with a separate core or circuit configuration. A compensated current corresponding to the detected components is applied. The compensated current is converged so that the magnetic flux generated by the compensated current cancels out the magnetic flux generated by the current under measurement, and the converged compensated current is measured to measure the current under measurement.

However, the flux-gate type current measuring devices according to the conventional art prepare for a configuration for generating an oscillation signal such as a sinusoidal wave or rectangular wave separately from the coil windings on the cores so that an oscillation signal from the configuration is simultaneously applied to the respective coil windings of the cores. Accordingly, the time constant is varied depending on the magnetic characteristics of the cores, and resultantly, the cores are incompletely magnetized due to application of the oscillation signal with a fixed frequency failing to reflect the magnetic characteristics of the cores, deteriorating the accuracy of current measurement. T0 eliminate such deterioration, an oscillation signal appropriate for the magnetic characteristics of the cores needs to be generated. However, since the error rate deviation of cores is significant in light of manufacture of current measuring devices, it is very difficult to tit the circuit elements for generating oscillation signals for the cores, and individual fitting for each manufactured measuring device is burdensome, thus causing a deterioration of productivity and performance.

Moreover, according to the conventional art, the coils are connected in series with each other (parallel as viewed from the connection node that is connected for input of an oscillation signal) so that both cores exhibit opposite polarities, and then, an oscillation signal is applied to the series connection node of the two coils so that the two cores are magnetized in opposite directions. Thus, even a small magnetization error occurring at the two cores may lead to a large deviation in measuring performance.

Meanwhile, according to the conventional art, the two cores are magnetized by the current under measurement flowing through the conducting wires as well as the oscillation signal. Accordingly, if the current under measurement is high, the cores may be saturated at the early stage of measurement and may be oscillated at a frequency even higher than the frequency of the oscillation signal, thus rendering it impossible to detect the DC component using the flux-gate method.

### SUMMARY

Accordingly, an object of the present invention is to provide a flux-gate type non-contact current measuring device that enables oscillation reflecting the magnetization characteristics of the cores through a self-oscillation that, rather than including an oscillation circuit for measuring current in the flux-gate method separately from the core coils, uses the core coils as a component of the oscillation circuit.

Another object of the present invention is to provide a flux-gate type non-contact current measuring device that enhances measurement accuracy by minimizing the influence from mutual electrical connections between currents applied to both cores in applying the current of an oscillation current to the cores to magnetize the cores to opposite polarities.

Still another object of the present invention is to provide a flux-gate type non-contact current measuring device that may normally measure current by automatically performing demagnetization when the cores to be magnetized with an oscillation signal are saturated by the current under measurement.

To achieve the above objects, according to the present invention, there is provided as flux-gate type non-contact current measuring device measuring a current under measurement by measuring a compensated current and configured so that a conducting wire W0 through which the current under measurement flows passes through a first core M1 around which as first coil W1 is wound, a second core M2 around which a second coil is wound W2, and a third core M3 around which a third coil W3 is wound, and a fourth coil is wound around all of the first, second, and third cores M1, M2, and M3, the compensated current is applied to the fourth coil W4 based on a current induced in the third coil W3 and currents of the first and second coils W1 and W2, which are oscillated in opposite polarities, the flux-gate type non-contact current measuring device comprising: an oscillation unit 10 producing an LC oscillation by an inductance of the first coil W1 and a capacitance of a capacitor C1 connected to the first coil W1 to apply a current to the first coil W1 and applying a current obtained by inverting a voltage polarity of the current applied to the first coil W1 to the second coil W2 so that the first core M1 and the second core M7 are magnetized in opposite polarities from each other, a compensated current generation unit 20 applying the compensated current corresponding to as voltage signal induced in the third coil W3 and a summed voltage signal of the first coil W1 and the second coil W2 to the fourth coil W4; and a detection unit 40 measuring the compensated current flowing through the fourth coil W4 to obtain the current under measurement.

The oscillation unit 10 applies a current, obtained by inverting-amplifying a voltage signal of the current applied to the first coil W1 using an operational amplifier (OP amp) A2 with a high input resistance characteristic, to the second coil W2 to prevent the current applied to the first coil W1 from being distorted by the current applied to the second coil W2.

The flux-gate type non-contact current measuring device further comprises a saturation return unit 30 turned on by a voltage of the capacitor C1 generated by a high-frequency oscillation created as the first core M1 is saturated, and in the turned-on state, amplifying the compensated current to demagnetize the first core M1.

The saturation return unit 30 is turned on by a positive (+) signal by allowing the voltage signal of the capacitor C1 to sequentially pass through as smoothing circuit and a diode D1.

The amplification in the compensated current generation unit 20 is performed by an OP amp A4 applying the summed voltage of the first coil W1 and the second coil W2 to an inverting (−) input end, applying the voltage induced in the third coil W3 to a non-inverting (+) input end, and feeding the output end back to the inverting (−) input end, and the saturation return unit 30 is connected to both ends of the feedback circuit of the OP amp A4 to inverting-amplify a voltage at the output end of the OP amp A4 and apply to the inverting (−) input end of the OP amp A4.

The saturation return unit 30 includes the smoothing circuit and the diode D1 for turning on the saturation return unit using the positive signal of the capacitor C1; an OP amp A5 inverting-amplifying a voltage signal corresponding to the compensated current; and as transistor T1 turned on by a positive (+) signal passing through the diode D1 to further amplify the signal amplified by the OP amp A5.

The first, second, and third cores M1, M2, and M3 each are configured of a cut core that may be dissembled and assembled, and protrusions and depressions are formed in connection surfaces of each core.

According to the present invention configured as above, in configuring an oscillation circuit for measuring current in a flux-gate method, a capacitor is connected to a coil wound around a core, thus producing a self-oscillation. Accordingly, the circuit may be simplified without the need of preparing for a separate sophisticated oscillation circuit, Magnetization is performed with an oscillation signal reflecting the characteristics of the core such as permeability, so that the DC component may be accurately detected in the fully magnetized state, thus increasing measurement performance.

Further, according to the present invention, one of two cores magnetized in opposite polarities is oscillated using a signal oscillated from the other. Accordingly, the influence between the two cores may be minimized using a circuit component such as the OP amp according to an embodiment of the present invention, and thus, the DC component may be precisely detected, allowing for accurate measurement of the current flowing through the conducting wire.

Further, according to the present invention, even when the core is saturated by the current flowing through the conducting wire at the early stage of the measurement prior to allowing the compensated current to flow, the high-frequency oscillation signal created by the saturation of the core may be sensed to allow the compensated current to flow for demagnetization. Accordingly, the saturation may be automatically released, leading to a normal measurement operatic Therefore, the present invention, when commercially used, does not cause malfunctions while eliminating the need of separate manipulation to release saturation, allowing for convenience in use.

### BRIEF DESCRIPTION OF THE DRAWINGS

FIG. 1 is a view illustrating the configuration of a flux-gate type non-contact current measuring device according to an embodiment of the present invention.

FIG. 2 is a perspective view schematically illustrating cores with coil-wound cores of a flux-gate type non-contact current measuring device according to an embodiment of the present invention.

FIG. 3 is an electric circuit view illustrating a flux-gate type non-contact current measuring device according to an embodiment: of the present invention.

FIG. 4 illustrates voltage waveforms of currents applied to magnetize cores of a flux-gate type non-contact current measuring device according to an embodiment of the present invention.

### DESCRIPTION OF EXEMPLARY EMBODIMENTS

Hereinafter, preferred embodiments of the present invention are described with reference to the accompanying drawings to be easily practiced by one of ordinary skill in the art.

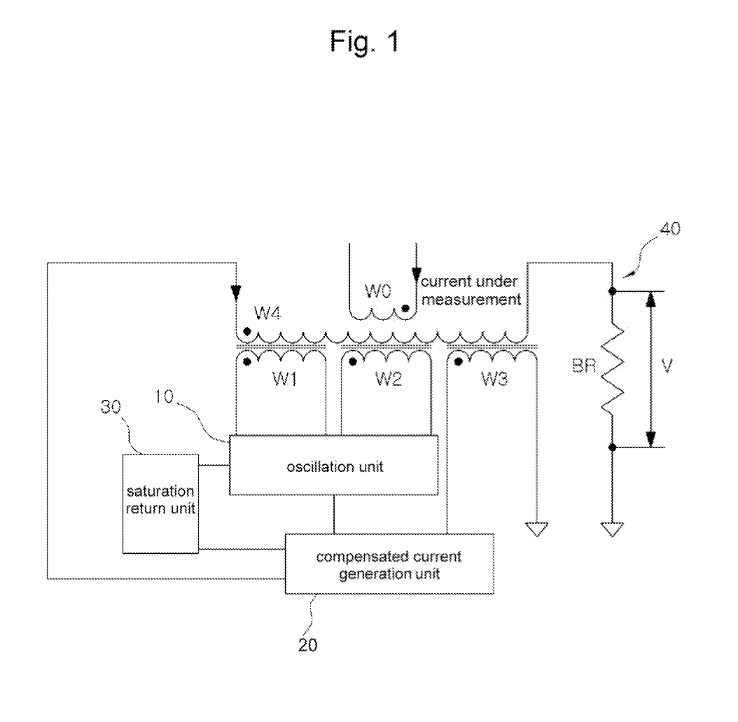

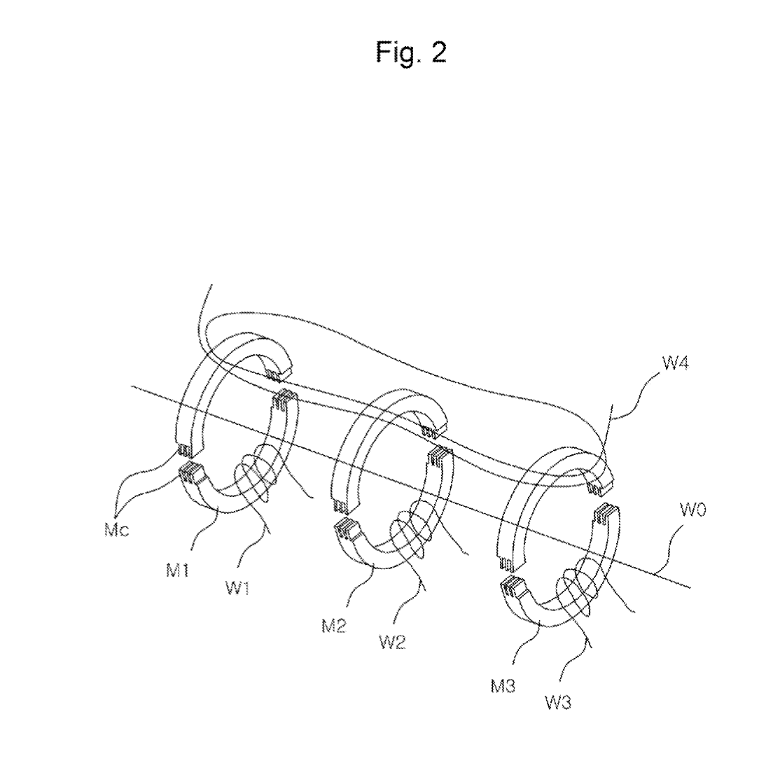

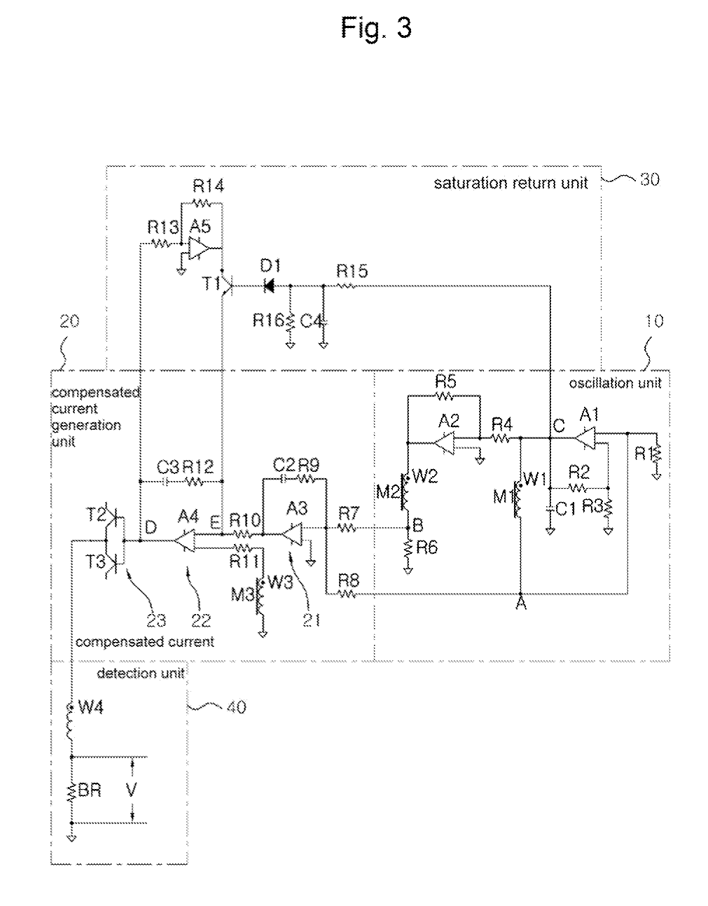

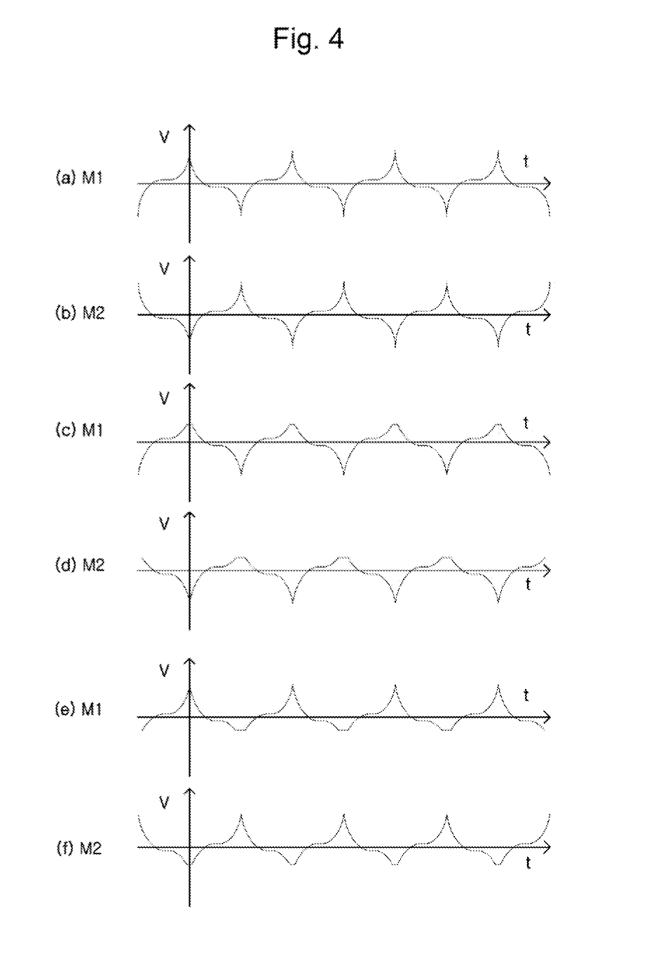

FIGS. 1 to 4 are views for describing a flux-gate type non-contact current measuring device according to an embodiment of the present invention. FIG. 1 is a view schematically illustrating the configuration of the flux-gate type non-contact current measuring device. FIG. 2 is a perspective view schematically illustrating coil-wound cores. FIG. 3 is a circuit view illustrating the flux-gate type non-contact current measuring device. FIG. 4 illustrates voltage waveforms of currents applied to magnetize first and second cores M1 and M2.

According to an embodiment of the present invention, the flux-gate type non-contact current measuring device includes three cores M1, M2, and M3 each surrounding a conducting wire W0 through which a current under measurement flows (so that the conducting wire passes through the cores), coils W1, W2, and W3 respectively wound around the three cores M1, M2, and M3, a coil W4 wound around all of the three cores M1, M2, and M3, an oscillation unit 10 applying oscillation currents with opposite polarities to two W1 and W2 of the three coils to magnetize the cores M1 and M2 around which the coils are wound with magnetic fluxes of opposite directions from each other, a compensated current generation unit 20 generating a compensated current corresponding to the applied oscillation currents and a current inducted in the other coil W3 of the three coils W1, W2, and W3, a saturation return unit 30 detecting when the cores are magnetically saturated and demagnetizing the same, and a detection unit 40 applying the compensated current to the coil W4 wound around all of the three cores and measuring a voltage created by the compensated current to obtain the current under measurement.

Here, the opposite polarities means that there is a phase difference of 180°.

The coils W1, W2, and W3 wound around the three cores M1, M2, and M3 include a first cod W1 that is applied with an AC (Alternating Current) current oscillated b the oscillation unit 10, a second that is applied with a current, having an opposite polarity of the current applied to the first coil W1, by the oscillation unit 10, and a third coil W3 for detecting an AC current inducted by the magnetic flux created by the AC component of the current under measurement as described below.

According to an embodiment of the present invention, the first, second, and third cores M1, M2, and M3 each are formed of a cut core that may be disassembled and assembled. The conducting wire W0 is put in with each core disassembled, and the core is then assembled so that the conducting wire W0 passes through the inside of the cores. This structure is used in clamp-type current measuring devices.

However, the magnetic flux resistance may be increased in the contact surfaces where the core is disassembled and assembled. According to an embodiment of the present invention, each core is formed to be disassembled and assembled and has protrusions and depressions Mc in the connection surfaces, which are engaged to fit into each other, significantly reducing the magnetic flux resistance. Here, the protrusions and depressions Mc may be prepared by forming grooves in one of the connection surfaces while forming protrusions in the other of the connection surfaces. As shown in FIG. 2, it is preferable to form multiple protrusions and depressions to increase the contact area. Of course, the protrusions and depressions Mc is preferably formed so that, when the protrusions and depressions Mc are fitted into each other, the contact surfaces come in tight contact with each other.

According to a specific embodiment of the present invention, the protrusions and depressions Mc are formed to have cuts from the outer surface to the inner surface and are shaped as a rectangular wave as viewed from outside to inside. However, the protrusions and depressions are not limited to such shape, and for example, may be shaped as saw teeth. Of course, each of the cut core-type first, second, and third cores M1, M2, and M3, when assembled, form a closed loop surrounding the conducting wire W0.

It is prefer, le to form the first, second, and third cores M1, M2, and M3 of a nano-crystal magnetic substance with high permeability and good frequency response and temperature characteristics to enable current measurement at the high performance of high accuracy and linearity. Nano crystal has high-frequency characteristics good enough to, when applied with a current oscillated at a constant frequency, keep the oscillation frequency stable as described below, and has high permeability that allows for accurate measurement.

The coil W4 wound around all of the three cores M1, M2, and M3 is denoted fourth coil W4 to be distinguished from the first, second, and third coils W1, W2, and W3.

As shown in FIGS. 1 and 2, the first, second, third, and fourth coils W1, W2, W3, and W4 are wound in the same direction, and the winding direction is marked with “” in the electric circuit view of FIG. 3.

The three cores M1, M2, and M3 include a first core M1 around which the first coil W1 is wound, a second core M2 around which the second coil W2 is wound, and a third core M3 around which the third coil W3 is wound, and are arranged in a line as if they are stacked one on another to have the conducting wire W0 through which the current under measurement flows sequentially pass through.

Accordingly, the first core M1 is magnetized by the magnetic flux created by a current applied to the first coil W1, and the second core M2 is magnetized by the magnetic flux created by a current applied to the second coil W2. In this case, since, the two currents have opposite polarities from each other, the magnetic flux lines Pace opposite directions. The first core M1 and the second core M2 are cores that enable detection of the DC magnetic flux component created by the DC component of the current flowing through the conducting wire W0 by the compensated current generation unit 20 as described below.

The third core M3 is a core for detecting the AC magnetic flux component created by the AC component of the current flowing through the conducting wire W0, and a current corresponding to the AC magnetic flux component is induced in the third coil W3.

As such, a compensated current corresponding to the AC magnetic flux component and DC magnetic flux component by the current under measurement flowing through the conducting wire W0 is applied to the fourth coil W4 by the compensated current generation unit 20 as described below.

The fourth coil W4 is wound around the bundle of first, second, and third cores M1, M2, and M3, and the magnetic flux created as the compensated current flows cancels out the magnetic flux created by the current under measurement flowing through the conducting wire W0, zeroing the total magnetic flux. According to the present invention, the circuit is configured so that the compensated current converges to a current zeroing the total magnetic flux at the moment of starting to measure the current under measurement.

Accordingly, the compensated current may be measured while converged, and the current wider measurement may be detected. To that end, the oscillation unit 10, the compensated current generation unit 20, the saturation return unit 30, and the detection unit 40 are described in detail below.

The oscillation unit 10 applies currents with a constant frequency to the first and second coils W1 and W2 so that the current applied to the first coil W1 and the current applied to the second coil. W2 have opposite polarities (i.e., a 180° phase difference between the polarities) and resultantly the respective magnetic fluxes of the first core M1 and the second core M2 are canceled out. To apply the currents of a constant frequency, the oscillation unit 10 is configured with an LC oscillation circuit that includes a capacitor C1 connected to the first coil W1, and an LC oscillation is produced by the inductance of the first coil W1 and the capacitance of the capacitor C1.

In other words, unlike the conventional art in which an independent oscillation circuit is included in the oscillation unit 10, an LC oscillation is produced by the first coil W1 wound around the first core M1, as an inductor, and the capacitor C1 connected to the inductor, according to the present invention.

Accordingly, the oscillation circuit may be simplified, and the concern that the first core is incompletely magnetized may be removed, enabling precise detection of the DC magnetic flux component. Specifically, applying a current to the first coil W1 with an oscillator independently configured to apply a current of a fixed frequency might not reflect the magnetization characteristics (i.e., permeability and time constant varied by the influence from the first coil) of the first core M1, resulting in a failure to magnetize the first core M1 fully enough to allow for exact detection of the DC magnetic flux component. In contrast, according, to the present invention, the oscillation is produced according to the time constant reflecting the inductance of the first coil W1 wound around the first core M1, and thus, the first core M1 may be completely magnetized to enable accurate detection of the DC magnetic flux component. This eliminates the need of fitting the specifications of the circuit elements for the characteristics of the first core M1 and the first coil W1 when configuring the oscillation unit 10, enhancing productability.

According to an embodiment of the present invention, the oscillation unit 10 includes an operational amplifier (OP amp) connected to the capacitor C1. Referring to FIG. 3, an end of the first coil W1 and an end of the capacitor C1 are connected to the output end C of the OP amp A1, and the other end of the first coil W1 is fed back to the inverting (−) input end of the OP amp A1, and the output end of the OP amp A1 is fed back to the non-inverting (+) input end via a resistor R2. The non-inverting (+) input end and the inverting (−) input end, respectively, are grounded via resistors R3 and R1. The other end of the capacitor C1 is grounded.

The oscillation unit 10 applies a current, obtained by inverting the voltage polarity of the current applied to the first coil W1, to the second coil W2. According to an embodiment of the present invention, an OP amp 12 is configured in circuit as an inverting amplifier, applying a current to the second coil W2. The connections of the OP amp A2 are described specifically with reference to FIG. 3, The output end of the OP amp A2 is fed back to the inverting (−) input end via a resistor R5, a resistor R4 is connected between the inverting (−) input end and the output end C of the OP amp A1 lot the oscillation of the first coil W1 and the non-inverting (+) input end is grounded, configuring the OP amp A2 as an inverting amplifier. The output end of the OP amp A2 is connected to an end of the second coil W2, and the other end B of the second coil W2 is grounded via a resistor R6.

As described above, the OP amp A2 is circuit-configured as an inverting amplifier to apply a current obtained by amplifying the current applied to the first cod W1 so that its voltage polarity is inverted to the second coil W2, thus enabling use of the characteristic of the OP amp with such a high input voltage as may be assumed to be infinite. That is, when applying the second coil W2 with the current obtained by inverting the voltage signal of the current applied to the first coil W1, the influence between the coils W1 and W2 may be minimized by the very high input resistance. Resultantly, despite the connection between the first coil W1 and the second coil W2, the first coil W1 is not influenced by the current applied to the second coil W2 thanks to the OP amp A2 circuit-configured as an inverting amplifier and connected in between, thus preventing a distortion of the current applied to the first coil W1.

The oscillation Unit 10 configured above may obtain the voltage signals of the currents respectively applied to the first and second coils W1 and W2 through the other end A of the first coil. W1 and the other end B of the second coil W2.

The compensated current generation unit 20 includes an adder 21 for summing the voltage signal of the current applied to the first coil W1 and the voltage signal of the current applied to the second coil W2, an amplifier 22 for amplifying the voltage signal of the current induced in the third coil W3 and the voltage signal summed by the adder 21, and a current drive 23 for generating a compensated current corresponding to a signal output from the amplifier 22. The compensated current generation unit 20 applies the compensated current generated by the current drive to the fourth coil W4.

That is, the voltage signal obtained by summing the voltage signal of the current applied to the first coil W1 and the voltage signal of the current applied to the second coil W2 corresponds to the DC component of the current under measurement, and the current induced in the third coil W3 corresponds to the AC component of the current under measurement. Accordingly, the voltage signal output from the amplifier 22 becomes a voltage signal for the current under measurement including both the DC component and the AC component. The circuit is configured so that the compensated current obtained by converting, the voltage signal with the current drive 23 is applied to the fourth coil W3. Accordingly, the compensated current is converged in a direction along which the DC component and AC component of the magnetic flux created by the current under measurement are reduced, i.e., in a direction approaching the current under measurement, and if the compensated current becomes equal to the current under measurement, the magnetic flux by the fourth coil W4 and the magnetic flux by the current under measurement are canceled out, zeroing the total magnetic flux. At this time, the detection unit 40 measures the compensated current flowing through the fourth coil W4, detecting the current under measurement.

Specific embodiments of the adder 21, the amplifier 22, and the current drive 23 configuring the compensated current generation unit 20 are described in detail with reference to FIG. 3.

The adder 21 is circuit-configured as an inverting amplifier with an OP amp A3 having an output end fed back to its inverting (−) input end sequentially passing through a capacitor C2 and a resistor R9. The non-inverting (+) input end of the OP amp A3 is grounded, and the other end A of the first coil W1 and the other end B of the second coil W2 are connected in parallel with the inverting (−) input end via resistors R7 and R8, respectively. Accordingly, the voltage signals respectively generated at the other end A of the first coil W1 and the other end B of the second coil W2 are summed and inverting amplified.

The principle of detecting the DC component of the current under measurement by the adder 21 is described taking the voltage waveforms of FIG. 4 as an example.

FIG. 4(a) and FIG. 4(b) shows graphs of voltage waveforms created by applying the oscillated electricity as described above to the first coil W1 wound around the first core M1 and the second coil W1 wound around the second core M2 when n current under measurement flows through the conducting wire W0. The voltage signal of the first coil W1 and the voltage signal of the second coil W2 have a phase difference of 180°. The voltage signals are summed to zero by the adder 21.

As a current under measurement with a positive DC component flows through the conducting wire W0, a positive portion of the voltage signal of the first coil W1 and a positive portion of the voltage signal of the second coil W2 are distorted as shown in FIG. 4(c) and FIG. 4(d). If the distorted voltage signals are summed by the adder 21, values other than zero are generated at the distorted portions, so that the positive DC component may be detected.

As a current under measurement with a negative DC component flows through the conducting wire W0, a negative portion of the voltage signal of the first coil W1 and a negative portion of the voltage signal of the second coil W2 are distorted as shown in FIG. 4(e) and FIG. 4(f). If the distorted voltage signals are summed by the adder 21, values other than zero are generated at the distorted portions, so that the negative DC component may be detected.

As such, if the current under measurement flowing through the conducting wire W0 includes a DC component, the DC component may be detected fitting the polarity.

The amplifier 22 is configured as a differential amplifier using an OP amp A4. The amplifier 22 is specifically described with reference to FIG. 3. The output end D of the OP amp A4 is fed hack to the inverting (−) input end C sequentially passing through a capacitor C3 and a resistor 12, and the output end of the OP amp A3 of the adder 21 is connected to the inverting (−) input end C via a resistor R10, and an end of the third coil W3 is connected to the non-inverting (+) input end of the OP amp A4 via a resistor R11, with the other end of the third coil W3 grounded.

Accordingly, the amplifier 22 differentially amplifies the DC voltage signal corresponding to the DC component of the current under measurement input through the inverting (−) input end and the AC voltage signal corresponding to the AC component of the current under measurement input through the non-inverting (+) input end. At this time, the voltage signal output through the output end D of the OP amp A4 of the amplifier 72 should reflect both the AC anti DC components of the current under measurement. To that end, the circuit may be designed considering the winding directions of the first, second, and third coils W1, W2, and W3, which one of both ends of each coil W1, W2, and W3 the voltage signal is withdrawn, and whether the adder 21 is inverting, and such circuit design is well known to one of ordinary skill in the art to which the present invention pertains, and thus, no detailed description thereof is given, in the end, the amplifier 22 plays a role to sum and amplify the DC voltage signal corresponding to the DC component of the current under measurement and the AC voltage signal corresponding to the AC component of the current under measurement.

The current drive 23 converts the voltage signal output from the amplifier 22 into a current signal, i.e., the compensated current for canceling out the magnetic flux created by the current under measurement, and applies the current to the fourth coil W4. Although the current drive 23 has two transistors T2 and T3 according, to an embodiment of the present invention, a proper amplifying circuit(s) among various known power amplifying circuits for generating and supplying a current corresponding to the voltage signal may be selected and used.

As described above, the compensated current by the oscillation unit 10 and the compensated current generation unit 20 is applied to the fourth coil W1.

The detection unit 40 is a component for measuring the current flowing through the fourth coil W1. According to an embodiment of the present invention, a burden resistor (BR) is connected in series with the fourth coil W1, and the voltage between both ends of the burden resistor BR is measured to measure the current.

As described above, the compensated current may be applied to the fourth coil W4 so that the magnetic flux by the compensated current cancels out the magnetic flux by the current wider measurement. If the magnetic flux by the current under measurement remains without fully canceled out, the remaining DC component of the current under measurement is detected by the oscillation unit 10 and the adder 21, and the remaining AC component of the current under measurement is detected by the third coil W3 and they are amplified by the amplifier 22. Accordingly, the compensated current increasingly converges until the compensated current cancels out, to zero, the magnetic flux of the current under measurement. In this sense, the compensated current may be interpreted as an inverse current of the current under measurement.

Accordingly, the current under measurement may be obtained by measuring a compensated current canceling out to zero the magnetic flux by the current under measurement using the detection unit 40 when the compensated current flows through the fourth coil W1. Of course, the current under measurement may be obtained by reflecting the number of times that the fourth coil W4 is wound, and this is well known in the technical field to which the present invention pertains.

Meanwhile, at the early stage of measuring the current under measurement of the conducting wire W0 using the current measuring device according to the present invention, the first core W1 may be saturated by the magnetic flux created by the current under measurement and the oscillation may be performed at an undesired high frequency. This happens particularly when the DC component of the current under measurement is very high. In such a high-frequency oscillation state, the current measuring device according to the present invention might not operate properly, rendering it difficult to measure the current under measurement. Accordingly, if saturation occurs at the early stage of the measuring operation, demagnetization is preferably performed to lead to a normal operation. The measuring device according to the present invention additionally includes the saturation return unit 30 as described, below, which demagnetizes the first core W1 when the first core W1 is saturated at the early stage of operation, thus enabling a normal LC oscillation by the oscillation unit 10.

The saturation return unit 30 senses a voltage by a high-frequency oscillation created as the first core M1 is saturated and performs a turn-on operation, and in the turn-on state, further amplifies the compensated current, inducing demagnetization of the first core M1.

The saturation return unit 30 is connected the output end D and inverting (−) input end E of the amplifier 22 of the compensated current generation unit 20, i.e., both ends of the feedback circuit of the OP amp A4 of the amplifier 22, in order to amplify the compensated current. The saturation return unit 30 inverting-amplifies the voltage signal of the output end D and applies to the inverting input end E. The saturation return unit 30 amplifies the compensated current from the amplifier 22 to a higher value than that obtained before the saturation return unit 30 is installed and allows the amplified compensated current to flow through the fourth coil W4.

Specifically, if the first core W1 is saturated by a very high current under measurement so that a high-frequency oscillation occurs, the voltage signal caused by the high-frequency oscillation appears in the capacitor C1 provided for LC oscillation. Accordingly, the saturation return unit 30 is configured to be turned on by receiving the voltage signal appearing in the capacitor C1. Referring to FIG. 3, the saturation return unit 30 includes a transistor T1 turned on depending on base voltages, an OP amp A5 inverting-amplifying the voltage signal corresponding to the compensated current, and a diode D1 and a smoothing circuit for sensing saturation. The circuit configuration is as follows.

According to the present invention, an end C of the capacitor C1 of the oscillation unit 10 is an end of the first coil and the output end of the OP amp A1, and a voltage signal generated at the end sequentially passes through the smoothing circuit and the diode D1 to the base of the transistor T1, so that the transistor T1 is turned on by the positive (+) voltage signal of the capacitor C1. Here, the smoothing circuit is provided midway of the conducting wire connecting between the end C of the capacitor C1 of the oscillation unit 10 and an end of the diode D1 in the order of a resistor R15 connected in series with the conducting wire and a capacitor C4 and a resistor R16 connected in parallel with each other between the conducting wire and the ground. A condition for turning on the transistor T1 may be set to comply with the specifications of the elements constituting the smoothing circuit, and the smoothing circuit may be considered a low pass filter.

The OP amp A5 inverting-amplifies the voltage signal corresponding to the compensated current of the output end D of the OP amp A4 constituting the amplifier 22 of the compensated current generation unit 20 and applies to the collector of the transistor T1. The inverting-amplifying circuit by the OP amp A5 is configured so that the non-inverting (±) input end is grounded, the output end is fed back to the inverting (−) input end via the resistor R14, the inverting (−) input end is connected to the output end D of the amplifier 22 via the resistor R13, and the output end is connected to the collector of the transistor T1.

The emitter of the transistor T1 is connected to the inverting (−) input end E of the OP amp A4 constituting the amplifier 22 of the compensated current generation unit 20.

The saturation return unit 30 configured as above switches the transistor T1 depending on the magnitude of the positive voltage signal of the capacitor C1 produced by the high-frequency oscillation created by the magnetic saturation of the first core M1 and further amplifies the compensated current when turning on the transistor T1 by the positive voltage signal of the capacitor C1 to perform reverse magnetization with further increased magnetic flux. Accordingly, the saturated first core M1 is gradually magnetized while positive currents and negative currents are alternately applied to the first coil W1 wound around the first core M1 escaping from the saturation.

As such, the first core M1 may be demagnetized by the switching operation of the saturation return unit 30. When the first core M1 is demagnetized, the saturation return unit 30 stops operating, and normal current measurement is performed by the oscillation unit 10 and the compensated current generation unit 20.

[Description of Elements]

| | |
|---|---|
| W0: Conducting wire | W1, W2, W3, W4: Coils |
| M1, M2, M3: Cores | 10: oscillation unit |
| 20: Compensated current generation unit | 21: Adder |
| 22: Amplifier | 23: Current drive |
| 30: Saturation return unit | 40: Detection unit |

What is claimed is:

1. A flux-gate type non-contact current measuring device measuring a current under measurement by measuring a compensated current and configured so that a conducting wire through which the current under measurement flows passes through a first core around which a first coil is wound, a second core around which a second coil is wound, and a third core around which a third coil is wound, and a fourth coil is wound around all of the first, second, and third cores, the compensated current is applied to the fourth coil based on a current induced in the third coil and currents of the first and second coils, which are oscillated in opposite polarities, the flux-gate type non-contact current measuring device comprising:
an oscillation unit producing an LC oscillation by an inductance of the first coil and a capacitance of a capacitor connected to the first coil to apply a current to the first coil and applying a current obtained, by inverting a voltage polarity of the current applied to the first coil to the second coil so that the first core and the second core are magnetized in opposite polarities from each other;
a compensated current generation unit applying the compensated current corresponding to a voltage signal induced in the third coil and a summed voltage signal of the first coil and the second coil to the fourth coil; and
a detection unit measuring the compensated current flowing through the fourth coil to obtain the current under measurement.

2. The flux-gate type non-contact current measuring device of claim 1, wherein the oscillation unit applies a current, obtained by inverting-amplifying a voltage signal of the current applied to the first coil using an operational amplifier (OP amp) with a high input resistance characteristic, to the second coil to prevent, the current applied to the first coil from being distorted by the current applied to the second coil.

3. The flux-gate type non-contact current measuring device of claim 1 or 2, further comprising a saturation return unit turned on by a voltage of the capacitor generated by a high-frequency oscillation created as the first core is saturated, and in the turned-on state, amplifying the compensated current to demagnetize the first core.

4. The flux-gate type non-contact current measuring device of claim 3, wherein the saturation return unit is turned on by a positive (+) signal by allowing the voltage signal of the capacitor to sequentially pass through a smoothing circuit and a diode.

5. The flux-gate type nom-contact current measuring device of claim 4, wherein the amplification in the compensated current generation unit is performed by an OP amp applying the summed voltage of the first coil and the second coil to an inverting (−) input end, applying the voltage induced in the thud coil to a non-inverting (+) input end, and feeding the output end back to the inverting (−) input end, and the saturation return unit is connected to both ends of the feedback circuit of the OP amp to inverting-amplify a voltage at the output end of the OP amp and apply to the inverting (−) input end of the OP amp.

6. The flux-gate type non-contact current measuring device of claim 5, wherein the saturation return unit includes the smoothing circuit and the diode for turning on the saturation return unit using the positive (+) signal of the capacitor; an OP amp inverting-amplifying a voltage signal corresponding to the compensated current; and a transistor turned on by a positive (+) signal passing through the diode to further amplify the signal amplified by the OP amp.

7. The flux-gate type non-contact current measuring device of claim 1, wherein the first, second, and third cores each are configured of a cut core that may be dissembled and assembled, and protrusions and depressions are formed in connection surfaces of each core.
